(19) United States
(12) Patent Application Publication
(10) Pub. No.: US 2017/0212203 A1
(43) Pub. Date: Jul. 27, 2017

(54) METHOD OF CALIBRATING STATE-OF-CHARGE IN A RECHARGEABLE BATTERY

(71) Applicant: Ovonic Battery Company, Inc., Rochester Hills, MI (US)

(72) Inventors: Kwo-hsiung Young, Troy, MI (US); Tiejun Meng, Novi, MI (US); Negar Mosavati, Grosse Pointe Park, MI (US)

(21) Appl. No.: 15/004,391

(22) Filed: Jan. 22, 2016

(51) Int. Cl. G01R 35/00; H01M 10/34; G01R 31/36; H01M 10/48

(52) U.S. Cl. CPC G01R 35/005; H01M 10/48; H01M 10/345; G01R 31/3606

(57) ABSTRACT

Provided are processes for the calibration of a battery system whereby a secondary battery is formed with an anode, a cathode, or both that includes two or more active materials that differ by at least one chemical or physical parameter. The presence of the two or more differing alloys in the system introduces at least one inflection point in the charge/discharge curves characterizing the system. The location of the inflection point relative to the fresh battery SOC is constant and independent of prior usage, cycling characteristics, or battery temperature. Therefore, by measuring the presence of the inflection point during a charge/discharge cycle or resting state, the exact SOC of the battery is known. If this measured SOC differs from a reference SOC by more than a predetermined value, the predetermined value is updated thereby calibrating the system for accurate display of SOC.

### FIELD OF THE INVENTION

This disclosure relates to batteries and battery systems. In particular, the disclosure relates to unique processes of calibrating and correcting for battery state of charge estimation which are independent of the state of health of the battery, temperature, or usage history.

### BACKGROUND OF THE INVENTION

The use of secondary batteries continues to grow with the ever increasing need for portable devices. The recent rapid expansion in the use of portable computers, cellular phones, and power tools creates a high demand for portable power systems. Also, battery systems are an essential component of automobiles and aircraft that depend on the power stored in these systems for safe and reliable operation.

The devices employing modern secondary batteries require robust battery-management features including charge control, battery capacity monitoring, remaining run-time information, compromisation of battery capacity and remaining run-time due to environmental conditions, charge-cycle counting, etc. Key to obtaining accurate information about battery condition is knowledge of the current state of charge (SOC). Understanding accurate state of charge will improve battery performance, reliability and lifetime. Several methods exist for determining battery state of charge including direct measurements, book-keeping, and adaptive systems, but each of these suffers numerous drawbacks.

Direct measurement methods for measuring SOC target the determination of particular battery variables such as voltage, impedance, or voltage relaxation time after application of a current step. Unfortunately, most of these variables are dependent on other factors such as battery temperature and the overall health of the battery such that the result obtained can be misleading. Further, measurement of some battery variables such as impedance as a function of frequency are impractical for portable devices.

Book keeping systems are based on current measurement and integration, or Coulomb counting. This and other data such as self-discharge rate, temperature, charge/discharge efficiency, etc. are maintained in a recorded book keeping system. These systems continuously monitor battery variables such as voltage, temperature, current, and integration. This information is fed to a processor that that uses the information to determine the state of charge. An issue with this type of system is that even small errors in the measurements can accumulate over time resulting in large errors in SOC determination.

Adaptive systems are typically a combination of direct measurement systems and book keeping systems. Typically mathematical models or Kalman filters are employed to compensate for user behavior or other factors that are related to battery usage or health.

In each of these systems, calibrating the SOC independent of irregular or unpredictable battery usage, environmental conditions and age is highly desired. Currently employed calibration models may use an ampere-hour method (accumulation based on charge-out and charge-in) to calculate SOC. However, self-discharge and discharge efficiency are both temperature sensitive and state-of-health (SOH) related. Therefore, it is difficult to get an accurate SOC for calibration when the battery is old or run at an irregular pattern using these methods.

Alternatively, correcting the SOC is historically achieved by measuring open-circuit-voltage and/or resistance. Unfortunately, both parameters are temperature and SOH sensitive such that a direct correlation is hard to establish. Also, in the range of SOC parameters that is most relevant to the particular battery type or application (e.g. 45%-55% of maximal capacity for some automobile applications) is quite small making accurate determination from these measurements in real world applications difficult.

As such, there is a need for methods of determining and calibrating battery state of charge that is independent of battery state of health, temperature, or usage history.

### SUMMARY OF THE INVENTION

The following summary is provided to facilitate an understanding of some of the innovative features unique to the present processes and is not intended to be a full description. A full appreciation of the various aspects of the processes can be gained by taking the entire specification, claims, drawings, and abstract as a whole.

Accurate determination of battery state of charge for the increasingly ubiquitous systems requiring portable power sources remains an unmet need in the marketplace. It is an object of this disclosure to provide methods for accurately determining battery state of charge or calibrating the state of charge in systems that employ secondary batteries. Processes of calibrating the state of charge of a secondary battery comprising an anode and a cathode, the anode, cathode or both comprising two or more active materials wherein at least two of the active materials in the cathode or anode are characterized by a different measurable physical or chemical property includes: measuring the physical or chemical property in the battery; identifying at least one inflection point characteristic of the at least two of the active materials in the cathode or anode characterized by the different measurable physical or chemical property; and calibrating the state of charge of the battery based on the identified location of the inflection point relative to a stored value, optionally updating the stored value based on the measured location of the inflection point. A primary power of the processes provided is the ability to place the inflection point in the “plateau region” of the voltage curve representing the most common and safest charge status of the battery. Unlike prior methods that may calibrate based solely on the well-known curve changes resulting from over-discharge or over-charge, the processes provided allow calibration from the normal and safe operating state of charge ranges of the battery. The inflection point is optionally between 10% and 90% full charge, optionally between 25% and 75% full charge, optionally between 45% and 55% full charge. The physical or chemical property differences of the two active materials are responsible for imparting the observable inflection point. Such physical or chemical property differences are optionally open circuit voltage, impedance, or resistance. In some aspects, the least two active materials are characterized by differing PCT pressure plateaus. In some aspects, the at least two active materials are characterized by differing open circuit voltages. Another power of the provided processes is the ability to function in all secondary battery types. A battery is optionally a NiMH, Ni—Zn, Ni—Fe, Li-ion, Na-ion, or Li—S battery. In some aspects, a battery is a metal hydride secondary battery and the at least two active materials are characterized by differing PCT pressure plateaus. The process may be achieved during a charge cycle, a discharge cycle, or a battery resting state such as in a diagnostic or calibration cycle. Optionally, the processes are performed when the battery is in a resting state. The measuring of the physical or chemical property is optionally performed in a resting state that is at least 1, 2, 3, 4, or 5 charge/discharge cycles (need not be full cycles) from a first use of the battery of a prior measuring step.

The objects of the disclosure are achieved by the processes provided herein. The processes have utility to provide much needed calibration of state of charge of secondary batteries and for the first time address the long felt need for accurate state of charge calibration that is independent of battery temperature, prior usage characteristics, or state of health.

### BRIEF DESCRIPTION OF THE DRAWINGS

FIG. 1 illustrates the open circuit voltage of a cell relative to hydrogen weight percentage at 25° C. with an anode that includes a single active material type (B37);

FIG. 2 illustrates the open circuit voltage of a cell relative to hydrogen weight percentage at 25° C. with an anode that includes two active material types that differ in PCT plateau pressure (B37 and B65 at a weight ratio of 10%/90%, respectively) illustrating the presence of an inflection point in the normal plateau region in both the charge and discharge curves;

FIG. 3 illustrates the open circuit voltage of alloy B65 as a function of hydrogen weight percentage illustrating no significant inflection point;

FIG. 4 illustrates the open circuit voltage of a cell using an anode employing a combination of alloy B37 and B65 at a weight ratio of 30%/70% respectively as a function of hydrogen weight percentage demonstrating the presence of a significant inflection point in both the charge and discharge curves;

FIG. 5A illustrates the open circuit voltage of a cell using an anode employing a combination of alloy B37 and B65 at a weight ratio of 50%/50% respectively as a function of hydrogen weight percentage demonstrating the presence of a significant inflection point in both the charge and discharge curves;

FIG. 5B illustrates the first derivative of the curve of FIG. 5A illustrating the clear demarcation and easy detectability of the inflection point in both the charging and discharging profiles as illustrated in FIG. 5A;

FIG. 6A illustrates the open circuit voltage of a cell using an anode employing a combination of alloy B37 and B65 at a weight ratio of 50%/50% respectively as a function of hydrogen weight percentage measured at 10° C. demonstrating the presence of a significant inflection point in both the charge and discharge curves that is independent of cell temperature; and

FIG. 6B illustrates the first derivative of the curve of FIG. 6A illustrating the clear demarcation and easy detectability of the inflection point in both the charging and discharging profiles as illustrated in FIG. 6A.

### DETAILED DESCRIPTION OF THE INVENTION

The following description of particular aspect(s) is merely exemplary in nature and is in no way intended to limit the scope of the invention, its application, or uses, which may, of course, vary. The invention is described with relation to the non-limiting definitions and terminology included herein. These definitions and terminology are not designed to function as a limitation on the scope or practice of the invention but are presented for illustrative and descriptive purposes only. While the processes or compositions are described as an order of individual steps or using specific materials, it is appreciated that steps or materials may be interchangeable such that the description of the invention may include multiple parts or steps arranged in many ways as is readily appreciated by one of skill in the art.

It will be understood that, although the terms “first,” “second,” “third” etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, “a first element,” “component,” “region,” “layer,” or “section” discussed below could be termed a second (or other) element, component, region, layer, or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. The term “or a combination thereof” means a combination including at least one of the foregoing elements.

Unless otherwise defined, all terms (including technical and scientific terms) used herein have the same meaning as commonly understood by one of ordinary skill in the art to which this disclosure belongs. It will be further understood that terms such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein the term “state of charge” or “SOC” is intended to mean the percentage of the maximum charge that is exhibited by a battery at a measurement time.

The term “state of health” or “SOH” is intended to mean a measurement that reflects the general condition of a battery and its ability to deliver a particular performance compared to a fresh battery.

The term “inflection point” as used herein is intended to define a portion on a curve where either the rate of change alters along the direction of the axis of abscissas optionally as measured by a local maximum in the first or higher order derivative, or the sign of curvature changes.

The term “calibrate” or “calibrating” are used to indicate the updating of a reference value to a measured value.

An “active material” is a material that participates in electrochemical charge/discharge reaction of the battery such as by absorbing or desorbing an ion such as hydrogen, lithium, sulfur or other ion.

Provided are processes for calibrating the state of charge of a secondary battery that is a result of particular and fixed chemical characteristics of the battery materials themselves that are, for the first time, entirely independent on battery state of health, temperature, usage history, measurement type, or other issues that historically made such calibrations difficult. The processes are used for secondary batteries that employ two or more active materials in an anode, a cathode, or both where the two or more active materials possess one or more differing physical or chemical properties. It was found that by combining these two or more differing active materials that the open circuit voltage profile of the material relative to state of charge includes one or more inflection points and these inflection points are independent of battery state of health, temperature, usage history or other issues as they are a characteristic of the active materials themselves. By scanning the battery during charge, discharge, or both during usage, a diagnostic cycle, or resting state, the calculated state of charge can be properly calibrated to the actual state of charge of the battery. The provided processes, therefore, represent a unique and powerful method of making absolute determinations of battery state of charge that fully integrate into existing measurement systems. The processes are suitable for use with any secondary battery chemistry such as batteries that employ lead-acid, NiMH, Ni—Zn, Ni—Fe, Ni—Cd, Li-ion, Na-ion, Li—S, molten salt, or redox flow battery systems.

A process of calibrating the state of charge of a secondary battery uses cells wherein the anode, cathode or both include two or more active materials wherein at least two of the active materials in the cathode, anode, or both are characterized by a different measurable physical or chemical property. The processes include: measuring a physical or chemical property of the battery, identifying at least one inflection point of the at least two of the active materials in the cathode or anode characterized by the different measurable physical or chemical property; and calibrating the state of charge of the battery based on the inflection point.

A physical or chemical property is optionally any measureable or observable characteristic of the battery or the active material(s). Illustrative examples of a physical property include open circuit voltage, impedance, and resistance. Illustrative examples of a chemical property are pressure-composition-temperature (PCT) isotherm properties such as PCT pressure plateau, among others. While much of the description is directed to open circuit voltage properties, it is appreciated that the same processes are equally conceived of with respect to PCT pressure plateau or other physical or chemical properties.

An anode, a cathode or both include two or more active materials that possess at least one differing physical or chemical property. The two different active materials differing in one or more physical or chemical properties are present in an anode or a cathode, or both an anode and a cathode each possess two or more such active materials. An anode, cathode, or both optionally include 2, 3, 4, 5, 6, or more active materials where at least two of the active materials differ in one or more chemical or physical properties. Optionally, all vary in the same chemical or physical property. Optionally two active materials differ in a first chemical or physical property and a second combination of active materials differ in a second chemical or physical property.

A difference in a chemical or physical property is any difference suitable to result in an inflection point in a measurement curve of the physical or chemical property value as it varies over state of charge. The absolute value of the difference will depend on the actual physical or chemical characteristic that does differ. As an example, two or more materials optionally possess differing PCI pressure plateaus that relate to different open circuit voltages of the materials. The two more materials optionally differ by 0.1% to 50% in the particular physical or chemical property, or any value or range therebetween. Optionally, two more materials optionally differ by a value dependent on the measured physical or chemical property of 0.1% to 10%, optionally 1 to 10%, optionally 0.1%, 0.2%, 0.3%, 0.4%, 0.5%, 0.6%, 0.7%, 0.8%, 0.9%, 1%, 2%, 3%, 4%, 5%, 6%, 7%, 8%, 9%, or 10% in the particular physical or chemical property.

The relative amounts of the two or more active materials may alter the location of the inflection point in the curve of measured physical or chemical property, but the location is constant and independent on the battery SOH, temperature, usage history, or other parameter that typically confounds traditional calibration of SOH. Thus, the relative ratio of the two materials may vary depending on the desired use of the battery and where the optimal point of the inflection point should lie. For example, some cell types are typically cycled only between, for example, 40% and 60% SOC due to desire to prevent overcharge and increase the maximal battery lifetime (e.g. cycle life). Thus, the relative ratio of the two or more materials is optionally chosen such that the inflection point lies within this SOC region. The weight percentage ratio of a first active material to a second active material optionally varies from 99%/1% to 1%/99% or any value or range therebetween. Optionally, the weight percentage ratio of a first active material to a second active material optionally varies from 90%/10% to 10%/90%, optionally 70%/30% to 30%/70%, optionally the weight percentage ratio of a first active material to a second active material optionally is 50%/50%.

A first active material and a second active material may be the same material or may be different materials. The materials may be the same or differ in chemical formula, amount of one or more components, physical structure, or other parameter or characteristic. In some aspects the reactive nature of the active materials is the same—i.e. both materials absorb and desorb the same ion types such as hydrogen, lithium, sulfur, or other ion, optionally at different affinities, rates, capacities, or other characteristic.

A process includes measuring the physical or chemical property in the battery, the electrode, or both. Measuring is achieved by any one of the methods well known in the art for measuring such properties. In exemplary aspects, open circuit voltage (OCV) is measured. OCV can be calculated by the following equation:

OCV=Vₜₑᵣₘ+IR (I)

where Vₜₑᵣₘ is the battery terminal voltage, I is the actual battery current expressed as a positive during discharge and a negative during charge, and R is the internal resistance. Processes of measuring one or more other physical or chemical properties of the battery are similarly understood in the art. The physical or chemical property is optionally measured during battery operation (either discharge or charge) or is determined during a diagnostic cycle optionally in a resting state. The value of the property is placed in a memory device or unit and used to generate a curve relative to a prior measurement such that an inflection point in the curve may be detected.

The process includes identifying at least one inflection point characteristic of the combined two active materials in the cathode or anode. The inflection point is a point where the rate of change in the curve changes above a certain threshold. During the charge, discharge, or resting state of a battery the voltage, optionally OCV, is measured over time or over course of charge. The presence of an inflection point in the open circuit voltage curve during the scan, charge or discharge is identified as a first or higher order derivative of the curve. The presence of this inflection point represents the constant value of state of charge. This known state of charge is then compared to a reference value of state of charge and if the difference between the measured state of charge differs from the reference value, the reference value is adjusted to the known value represented by the inflection point. Methods of identifying an inflection point in a charge/discharge curve of an electrochemical cell are known as illustrated by U.S. Pat. Nos. 4,677,363 and 5,612,607.

The power of the present method is that the inflection point is not only constant over the course of battery lifetime and independent on the SOH, usage, temperature, or other battery experience, but it allows for the introduction of a measurable inflection point within the normally flat plateau region where the majority of secondary batteries operate, thereby negating the need to reach a full or near full state of charge, or a full or near full state of discharge in the battery for the identification of the inflection point.

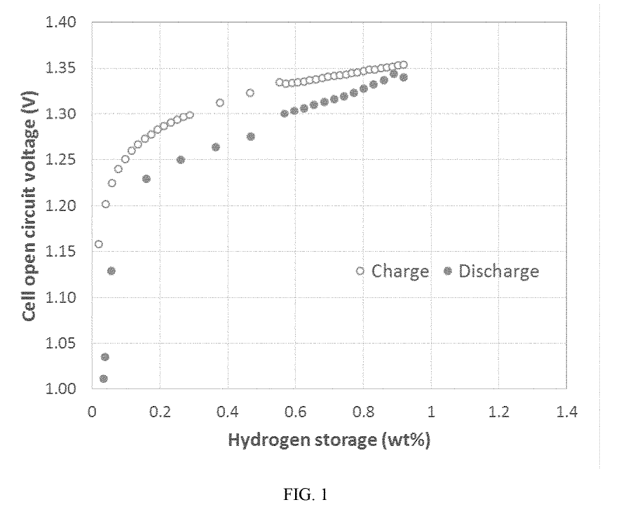

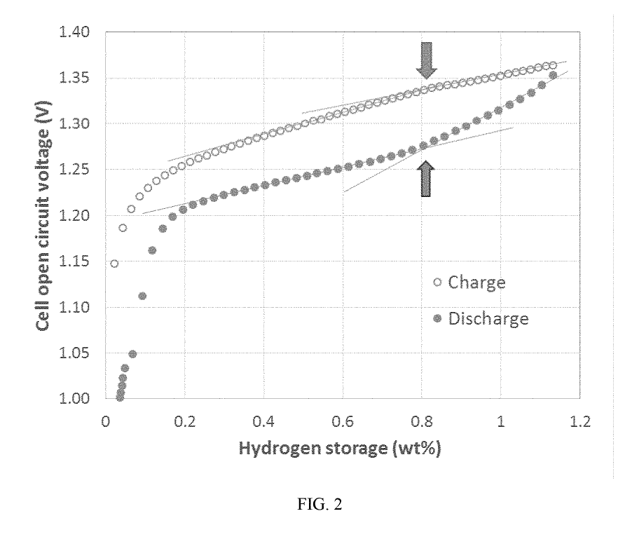

An example of the process is illustrated by comparing FIGS. 1 and 2. FIG. 1 depicts a standard charge discharge curve measuring the OCV as it relates to state of charge for a single active material. A similarly flat curve is obtained if two or more active materials that do not differ in a physical or chemical characteristic observable by OCV are combined. As expected at nearly full discharge voltage (i.e. less than 0.2 hydrogen wt %) the curve shows the expected increase in the rate of voltage drop, however, at the operational levels of the cell (e.g. 0.2 to 0.9 hydrogen wt %) the voltage curve is essentially flat. This section represents the normal cycling area for a secondary battery. No significant changes are observed in this plateau region.

FIG. 2 illustrates the same measurement curve for an electrode formed of two active materials that differ in PCT plateau values thereby producing different OCV curves relative to SOC (as depicted by hydrogen wt %). Unlike FIG. 1, the area that is expected to represent the plateau over the whole region, the SOC curves for the two active material systems illustrate a distinct inflection point (I_{C} and I_{D}) in each. These inflection points are constant and independent of battery SOH, temperature, usage, or other issue and represent a constant and known SOC that is invariant over the life of the battery. Moreover, the presence of this inflection point within the normal plateau region of the curve allows for more accurate and real life determination of the actual battery SOC without the need to reach a full SOC (risking reaching an overcharge state), or a near total discharge state (which will decease battery lifetime).

Thus, the displayed or reference SOC is readily adjusted if this reference value differs from the measured state of charge by a predetermined value to thereby calibrate the state of charge as recognized by the system. Such values are readily updated in charge control or other battery control systems by processes essentially described in U.S. Pat. Nos. 4,320,334, 4,677,363, and 5,612,607.

It is further appreciated that the location of the inflection point is optionally adjusted by adjusting the relative amounts or types of active materials to lie at or within 10% to 90% full charge in the battery, optionally 15% to 85%, optionally 25% to 75%, optionally 45% to 55% of full charge. Above 90% lies an inflection point representative of nearing overcharge which is avoided by the present processes. Similarly, below 10% lies an inflection point representative of over-discharge which is also avoided by the present processes. As such, the inflection point is optionally included to lie within the known points representing over-charge or over-discharge. The over-charge or over-discharge inflection points are illustrated in U.S. Pat. No. 4,677,363 and are optionally excluded in the present processes. Optionally, the location of the inflection point is optionally set during the formation of the anode, cathode, or both by adjusting the relative amounts or types of active materials to lie at or within 10% to 90% full charge in the battery, or any value or range therebetween or as taught herein. Optionally, the location of the inflection point is optionally adjusted by adjusting the relative amounts or types of active materials to lie at or within 45% to 55% full charge in the battery.

A SOC is optionally calibrated during an active or resting state of the battery. An active battery state is understood to be during a charge or discharge of the cell, excluding spontaneous discharge. A resting state is a state of the battery that is not in active charge or discharge of the cell as per normal device usage requirements, but may include diagnostic or calibration charging or discharging conditions. For example, a battery monitoring system may be employed to perform a diagnostic cycle on a cell such as during a time of no expected device usage. A diagnostic cycle may include discharging a cell down to an expected lower state of charge, illustratively 40%, and undergo a step charging process whereby the open circuit voltage is assessed at each 2% step of charge. The process is continued until an expected upper charge state of the battery. The inflection point in the OCV curve is designed into the battery to fall within the expected lower charge state and expected upper charge state so that the presence of the inflection point may be observed during this diagnostic or calibration cycle. Upon recognition of the inflection point, the value of the state of charge based on the prior diagnostic cycle or from a new battery is updated such that the charge of the inflection point is the newly measured state of charge to be stored in the battery management system thereby representing a calibrated state of charge. The newly stored state of charge is then used by the system to display to the user the calibrated state of charge until the next diagnostic or calibration cycle is used. Similarly, the processes can be achieved by bringing the battery up to the expected upper charge state (e.g. 60% SOC) and then discharged though a dummy load with a 2% open circuit voltage measurement taken until an expected lower charge state is reached. The presence of the inflection point in the discharge curve is then similarly used to calibrate the stored state of charge value and update it if the stored value is outside of a predetermined range from the measured state of charge at the inflection point. As a further illustration, if the inflection point lies at a 50% state of charge, if the location of the inflection point is found to be at the 45% stored value, the stored value is updated to adjust for this difference and the battery monitoring system is thereby calibrated so that the measured inflection point is stored in the system as a 50% state of charge.

Optionally, a diagnostic or calibration cycle is set by the battery monitoring system to occur over a set period of time or battery usage. In some aspects, a calibration cycle is employed with each battery charge/discharge cycle. Optionally, 2, 3, 4, 5, 6, 7, 8, 9, 10 or more charge/discharge cycles will fall between two diagnostic or calibration cycles. For example, a battery monitoring system may be employed such that a calibration cycle is activated following 5 charge/discharge cycles of the battery. Such processes allow for ready calibration of the state of charge at any predetermined interval as required by the battery monitoring system.

Various aspects of the present invention are illustrated by the following non-limiting examples. The examples are for illustrative purposes and are not a limitation on any practice of the present invention. It will be understood that variations and modifications can be made without departing from the spirit and scope of the invention.

### Experimental

An experimental series was carried out in which a group of hydrogen absorbing alloy materials suitable for use in a metal hydride electrochemical cell were prepared. Briefly, a series of sample ingots were prepared by induction melting performed under an argon atmosphere in a 2 kg furnace using a MgAl₂O₄ crucible, an alumina tundish, and a steel pancake-shape mold. The annealing of ingots was done in vacuum (<1 mtorr) at 960° C. for 8 h with 1 hour ramp-up and natural cooling afterward. The initial cooling rate was estimated at about one hundred degrees C. per second. The resulting alloys were then pulverized and sifted. The chemical composition of each sample was examined by a Varian Liberty 100 inductively-coupled plasma (ICP) system. The alloys produced had the following formulas: La_{9.6}Ce_{4.0}Pr_{0.5}Nd_{1.3}Ni_{65.8}Co_{4.6}Mn_{4.2}Al_{5.5}Cu_{4.6} (B37) and La_{10.5}Ce_{4.3}Pr_{0.5}Nd_{1.4}Ni_{62.3}Co_{5.0}Mn_{4.6}Al_{6.0}Cu_{3.2}Zr_{0.2}Mo_{2.0} (B65) with the numbers representing the atomic percentages of the elements in the final product. For PCT analyses, each ingot piece (about 2 g) was first activated by a 2 h thermal cycle between room temperature and 300° C. under 2.5 MPa H₂ pressure and then measured at 30° C. 60° C. and 90° C. using a Suzuki-Shokan multi-channel pressure-concentration-temperature device (PCT, Suzuki Shokan, Tokyo, Japan). As measured by PCT at 30° C., alloy B37 had a maximum hydrogen storage capacity of 1.34 wt % and alloy B65 had a maximum hydrogen storage capacity of 1.21 wt %. The B37 desorption pressure plateau was 0.088 MPa and the B35 desorption pressure plateau was 0.012 MPa.

The anode active materials were assessed for electrochemical function by the electrochemical pressure-concentration temperature (EPCT) method. Using this method, the stabilized OCV obtained experimentally is ideally in close proximity to the equilibrium potential of the battery. For the half-cell Ni/MH configuration used in this study, the partially charged positive electrode has a constant potential of 0.36 V vs. Hg/HgO and E_{MH. eq} (vs. Hg/HgO)≈OCV−0.36 (V).

The anode materials are therefore studied by EPCT using anode active material ground into a −200 mesh size. The sieved powder was then compacted onto an expanded nickel metal substrate by a continuous roll mill. The open circuit voltage of these alloys were evaluated in a flooded-cell configuration (electrolyte—30 wt % KOH solution) using a partially pre-charged anode against an oversized Ni(OH)₂ counter electrode as the positive electrode. Before the EPCT measurement, the electrode samples were activated with 10 charge/discharge cycles at 25 mA/g at room temperature using a CTE MCL2 Mini (Chen Tech Electric MFG. Co., Ltd., New Taipei, Taiwan) cell test system. The electrochemical properties were evaluated at room temperature (25° C.) or 10° C. Each charge/discharge step was 15 minutes in length at a 25 mA/g rate and rest for 30 minutes and the electrochemical OCV was recorded at the end of the 30 min. rest after each charge/discharge step.

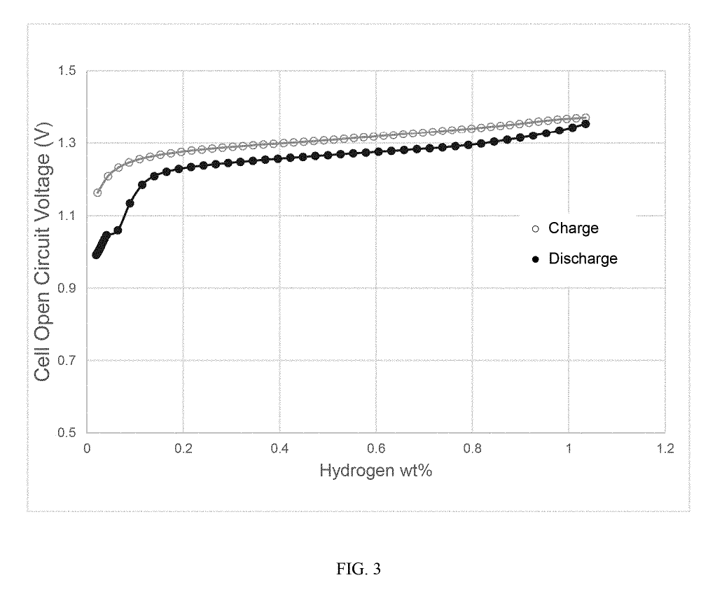

As illustrated in FIG. 1, alloy B37 (an AB₅ structured alloy) shows an OCV with the expected voltage plateau between hydrogen weight percentages of 0.2 and 0.9. Neither the charge or discharge curve illustrate a significant inflection point. Similar results are depicted in FIG. 3 illustrating a second ABs structured alloy (B65) that differs in PCT plateau pressure and corresponding OCV levels. The curves similarly show no significant inflection point in either the charge or discharge curves.

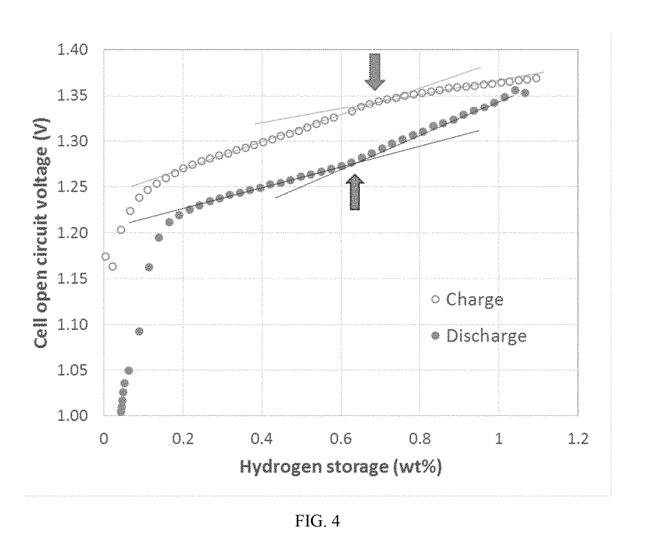

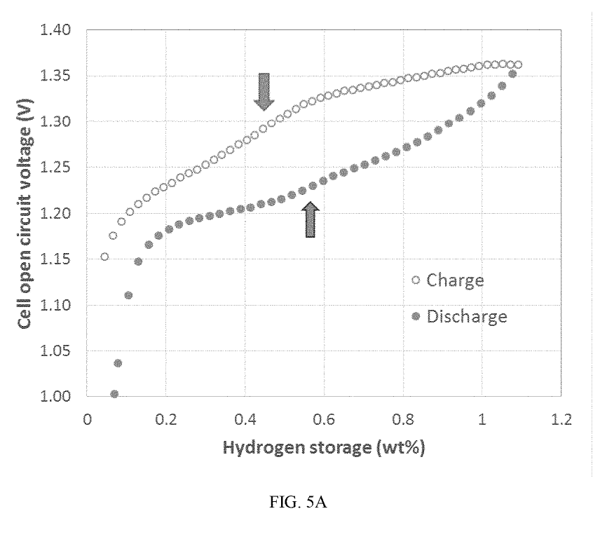

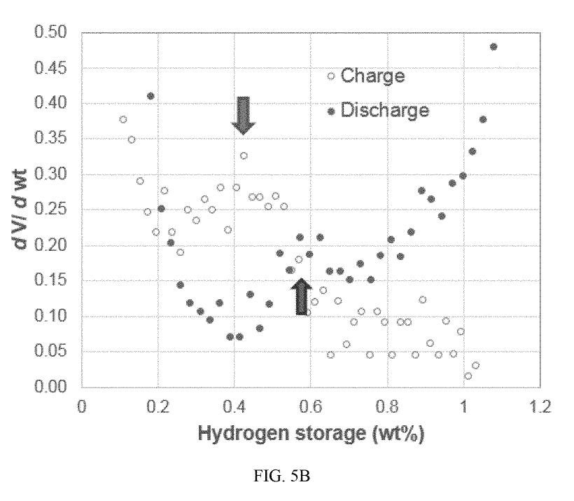

The alloys of B37 and B65 are then intermixed in the formation of the anodes and tested under the same conditions as for the single active agent species anodes. The alloys are mixed at B37/B65 ratios of 10%/90%, 30%/70%, and 50%/50% by weight. The resulting curves for each of these ratios are illustrated in FIGS. 2, 4, and 5 respectively. Each of the resulting figures shows a distinct inflection point in both the charge and discharge curves located within the plateau region for each of the alloys when individually tested (compare to FIGS. 1 and 3). The location of this inflection point with respect to hydrogen wt % moves from the lower end of the plateau region in the anode with the highest amount of B37 to the higher end of the plateau region for the anode with the lower amount of B37 alloy. The location of the inflection point is clearly revealed in the first derivative of the data presented in FIG. 5A showing clear demarcation of the inflection points in both the charge and discharge curves where the inflection point is clearly located in the plateau region.

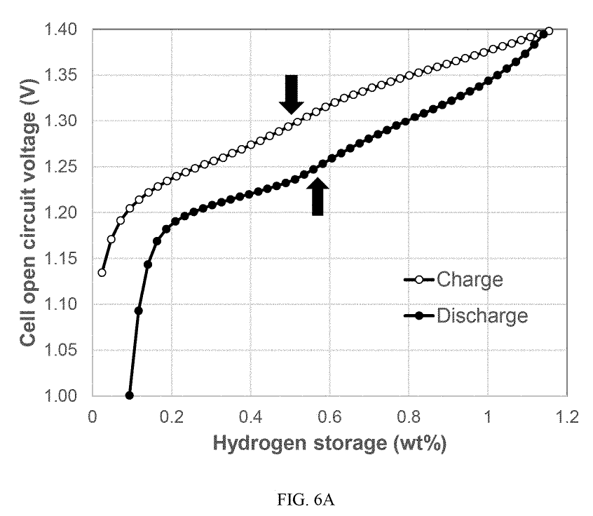

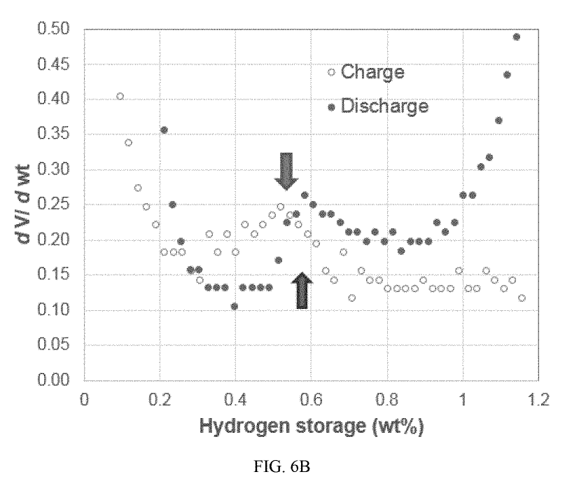

FIG. 6A illustrates similar studies with equal amounts of B37 and B65 (i.e. 50%/50%) active materials in the anode, but with the test run at 10° C., and FIG. 6B illustrates the first derivative of the data in FIG. 6A. The location of the inflection point is indistinguishable from the cell run at 25° C. illustrating the temperature independence of the inflection point location relative to SOC. The location of the inflection point is constant and independent of cell temperature or number of prior cycles run. Also, the position of the inflection point is a characteristic of the particular alloys used in the formation of the anode as well as the relative amounts of each of the two or more active materials. Thus, upon detection of this inflection point, the exact SOC is readily determined. If a reference SOC differs by more than a predetermined value such as 2%, the charging or monitoring system updates the reference value to match the measured SOC thereby fully calibrating the SOC in the system.

Patents, publications, and applications mentioned in the specification are indicative of the levels of those skilled in the art to which the invention pertains. These patents, publications, and applications are incorporated herein by reference to the same extent as if each individual patent, publication, or application was specifically and individually incorporated herein by reference.

In view of the foregoing, it is to be understood that other modifications and variations of the present invention may be implemented. The foregoing drawings, discussion, and description are illustrative of some specific embodiments of the invention but are not meant to be limitations upon the practice thereof. It is the following claims, including all equivalents, which define the scope of the invention.

1. A process of calibrating the state of charge of a secondary battery comprising an anode and a cathode, the anode, cathode or both comprising two or more active materials wherein at least two of the active materials in the cathode or anode are characterized by a different measurable physical or chemical property, the process comprising:
measuring the physical or chemical property in the battery;
identifying at least one inflection point characteristic of the at least two of the active materials in the cathode or anode characterized by the different measurable physical or chemical property; and
calibrating the state of charge of said battery based on said inflection point.

2. The process of claim 1 wherein the inflection point is between 10 percent and 90 percent full charge.

3. The process of claim 1 wherein the inflection point is between 25 percent and 75 percent full charge.

4. The process of claim 1 wherein the inflection point is between 45 percent and 55 percent full charge.

5. The process of claim 1 wherein the physical or chemical property is open circuit voltage, impedance, or resistance.

6. The process of claim 1 wherein the at least two active materials are characterized by differing PCT pressure plateaus.

7. The process of claim 1 wherein the at least two active materials are characterized by differing open circuit voltages.

8. The process of claim 1 wherein the battery is a NiMH, Ni—Zn, Ni—Fe, Li-ion, Na-ion, or Li—S battery.

9. The process of claim 1 wherein said battery is a metal hydride secondary battery and the at least two active materials are characterized by differing PCT pressure plateaus.

10. The process of claim 1 wherein said battery is a resting state.

11. A process of calibrating the state of charge of a secondary battery comprising an anode and a cathode, the anode, cathode or both comprising two or more active materials wherein at least two of the active materials in the cathode or anode are characterized by a different measurable physical or chemical property, the process comprising:
measuring the physical or chemical property in the battery when in a resting state, the resting state at least 5 cycles following a prior calibration process;
identifying at least one inflection point characteristic of the at least two of the active materials in the cathode or anode characterized by the different measurable physical or chemical property, the inflection point between 25 percent and 75 percent full charge; and
calibrating the state of charge of said battery based on said inflection point.

12. The process of claim 11 wherein the physical or chemical property is open circuit voltage.

13. The process of claim 11 wherein the at least two active materials are characterized by differing PCT pressure plateaus.

14. The process of claim 11 wherein the at least two active materials are characterized by differing open circuit voltages when measured at the same state of charge.

15. The process of claim 11 wherein the battery is a lead-acid, NiMH Ni—Zn, Ni—Fe, Ni—Cd, Li-ion, Na-ion, Li—S, molten salt, or redox flow battery systems.

16. The process of claim 11 wherein the two of the active materials are present at a weight ratio of 10 percent-90 percent to 90 percent-10 percent.

17. The process of claim 11 wherein the two of the active materials are present at a weight ratio of 25 percent-75 percent to 75 percent-25 percent.

18. The process of claim 11 wherein the two of the active materials are both hydrogen absorbing alloys or lithium containing compounds.
